(19) United States
(12) Patent Application Publication
(10) Pub. No.: US 2024/0072745 A1
(43) Pub. Date: Feb. 29, 2024

(54) DIFFERENTIAL AMPLIFIER

(71) Applicant: LAPIS Technology Co., Ltd., Yokohama (JP)

(72) Inventors: Tetsuo OOMORI, Yokohama (JP); Shingo TANIGUCHI, Yokohama (JP)

(73) Assignee: LAPIS Technology Co., Ltd., Yokohama (JP)

(21) Appl. No.: 18/451,820

(22) Filed: Aug. 17, 2023

(30) Foreign Application Priority Data
Aug. 25, 2022 (JP) 2022-134054

(51) Int. Cl. H03F 3/45

(52) U.S. Cl. CPC H03F 3/45269; H03F 2203/45116

(57) ABSTRACT

A differential amplifier includes a first input terminal, second input terminals, output terminals, differential amplification circuits, and a current source circuit. The first input terminal is one of an inverting input terminal and a non-inverting input terminal. Each of the second input terminals is another of the inverting input terminal and the non-inverting input terminal. The output terminals output voltages respectively corresponding to the second input terminals. The differential amplification circuits are connected to the first input terminal and the second input terminals and are provided corresponding to the second input terminals. The current source circuit is connected to the differential amplification circuits. Each of the differential amplification circuits outputs an output voltage corresponding to a combination of a voltage inputted to the first input terminal and a voltage inputted to one of the second input terminals from a corresponding one of the output terminals.

### CROSS-REFERENCE TO RELATED APPLICATION

This application claims the priority benefit of Japan application serial no. 2022-134054, filed on Aug. 25, 2022. The entirety of the above-mentioned patent application is hereby incorporated by reference herein and made a part of this specification.

### BACKGROUND

### Technical Field

The disclosure relates to a differential amplifier.

### Related Art

Conventionally, in a large-scale system mounted with microcontrollers, AD/DA converters, motors, various communication systems, various sensors, etc., a regulator of a stabilized power supply circuit is generally used as a power supply of such a large-scale system.

The regulator is generally composed of an operational amplifier, an output transistor, and a feedback resistor.

Further, the operational amplifier is used as various types of amplifiers such as an inverting amplifier and a non-inverting amplifier composed of an input resistor and a feedback resistors, as an output buffer such as a voltage follower, and also as a component of various analog circuits such as a comparator taking an inverter as an output.

Patent Document 1 (Japanese Patent Application Laid-Open No. 2014-92869) discloses a configuration in which an operational amplifier, an output transistor, and a voltage dividing circuit are provided for a regulator.

Patent Document 2 (Japanese Patent Application Laid-Open No. 2021-18657) discloses a technique of controlling two output transistors respectively with different operational amplifiers for a series regulator.

Generally, the regulator uses an operational amplifier composed of a differential amplifier as in Patent Document 1. In a large-scale system, a plurality of regulators are required as in Patent Document 2. In other words, in the case where a plurality of regulators are provided as in a large-scale system, it is required to provide a plurality of differential amplifiers along with the regulators.

Furthermore, in a regulator, an amplifier, an output buffer, etc., since characteristics may deteriorate due to an overshoot of output, an undershoot, noise, or output distortion depending on the circuit connected to an output terminal, there may be cases where it cannot be connected in combination with other circuits to the same output terminal. For this reason, it is required to prepare individual regulators, amplifiers, and output buffers for these circuits. Thus, the circuit scale may increase.

### SUMMARY

A differential amplifier according to an embodiment of the disclosure includes a first input terminal, a plurality of second input terminals, a plurality of output terminals, a plurality of differential amplification circuits, and a current source circuit. The first input terminal is one of an inverting input terminal and a non-inverting input terminal. Each of the plurality of second input terminals is another of the inverting input terminal and the non-inverting input terminal. The plurality of output terminals output voltages respectively corresponding to the plurality of second input terminals. The plurality of differential amplification circuits are connected to the first input terminal and the plurality of second input terminals and are provided corresponding to the plurality of second input terminals. The current source circuit is connected to the plurality of differential amplification circuits. Each of the plurality of differential amplification circuits outputs an output voltage corresponding to a combination of a voltage inputted to the first input terminal and a voltage inputted to one of the plurality of second input terminals from one of the plurality of output terminals.

A regulator according to an embodiment of the disclosure includes the above differential amplifier, and a plurality of output transistors connected to the plurality of output terminals. A plurality of feedback nodes connected to the plurality of output transistors are connected to the plurality of second input terminals. A reference voltage is inputted to the first input terminal.

An operational amplifier according to an embodiment of the disclosure includes the above differential amplifier, and a plurality of amplification circuits connected to the plurality of output terminals.

A comparator according to an embodiment of the disclosure includes the above differential amplifier, and a plurality of inverter circuits connected to the plurality of output terminals.

A differential amplifier according to an embodiment of the disclosure includes a first differential stage circuit, a second differential stage circuit, a first load circuit, a second load circuit, and a current source circuit. A reference voltage and a first input voltage are inputted to the first differential stage circuit. The reference voltage and a second input voltage are inputted to the second differential stage circuit. The first load circuit is provided between the first differential stage circuit and a first potential. The second load circuit is provided between the second differential stage circuit and the first potential. The current source circuit is provided between a second potential, which is different from the first potential, and the first differential stage circuit and the second differential stage circuit.

A differential amplifier according to an embodiment of the disclosure includes a differential stage circuit, a load circuit, and a current source circuit. The differential stage circuit includes a first transistor to which a reference voltage is inputted, a second transistor to which a first input voltage is inputted, and a third transistor to which a second input voltage is inputted. The load circuit is provided between the differential stage circuit and a first potential. The current source circuit is connected to the first transistor, the second transistor, and the third transistor. The differential stage circuit forms a first differential pair with the first transistor and the second transistor, and forms a second differential pair with the first transistor and the third transistor.

According to the embodiments of the disclosure, a differential amplifier capable of suppressing an increase in the circuit scale by realizing multiple inputs and multiple outputs, and a regulator, an operational amplifier, and a comparator including the differential amplifier are provided.

### BRIEF DESCRIPTION OF THE DRAWINGS

FIG. 1 is a circuit block diagram showing a configuration of a differential amplifier according to a first embodiment of the disclosure.

FIG. 2 is a circuit block diagram showing a configuration of a differential amplifier according to a second embodiment of the disclosure.

FIG. 3 is a circuit block diagram showing a configuration of a differential amplifier according to a third embodiment of the disclosure.

FIG. 4 is a circuit block diagram showing a configuration of a differential amplifier according to a fourth embodiment of the disclosure.

FIG. 5 is a circuit block diagram showing a configuration of a regulator according to a fifth embodiment of the disclosure.

FIG. 6 is a graph showing a characteristics diagram of an output voltage of the regulator according to the fifth embodiment of the disclosure.

FIG. 7 is a circuit block diagram showing configurations of an operational amplifier according to a sixth embodiment and a comparator according to a seventh embodiment of the disclosure.

FIG. 8 is a circuit block diagram showing the configuration of the operational amplifier according to the sixth embodiment of the disclosure.

FIG. 9 is a circuit block diagram showing a configuration of an inverting amplifier including the operational amplifier according to the sixth embodiment of the disclosure.

FIG. 10 is a graph showing a characteristics diagram of an output voltage of the inverting amplifier.

FIG. 11 is a circuit block diagram showing a configuration of a non-inverting amplifier including the operational amplifier according to the sixth embodiment of the disclosure.

FIG. 12 is a graph showing a characteristics diagram of an output voltage of the non-inverting amplifier.

FIG. 13 is a circuit block diagram showing a configuration of a voltage follower including the operational amplifier according to the sixth embodiment of the disclosure.

FIG. 14 is a graph showing a characteristics diagram of an output voltage of the voltage follower.

FIG. 15 is a circuit block diagram showing a configuration of the comparator according to the seventh embodiment of the disclosure.

FIG. 16 is a circuit block diagram showing a configuration of a comparison device including the comparator according to the seventh embodiment of the disclosure.

FIG. 17 is graph showing a characteristics diagram of an output voltage of the comparison device.

FIG. 18 is circuit block diagram showing a configuration of a differential amplifier according to the related art.

FIG. 19 is circuit block diagram showing a configuration of a differential amplifier according to the related art.

### DESCRIPTION OF THE EMBODIMENTS

Embodiments of the disclosure provide a differential amplifier capable of suppressing an increase in the circuit scale by realizing multiple inputs and multiple outputs, and a regulator, an operational amplifier, and a comparator including the differential amplifier.

Hereinafter, embodiments of the disclosure will be described with reference to the drawings. In each drawing, substantially identical or equivalent constituent elements or parts will be labeled with the same reference signs.

### Overview of Embodiments of Disclosure

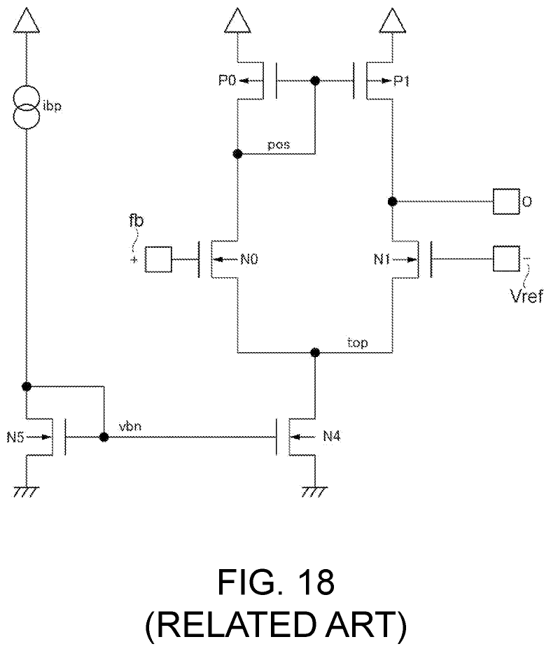

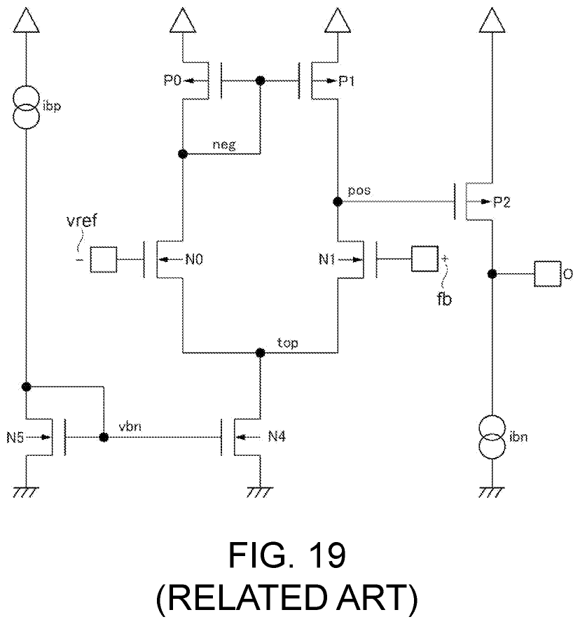

FIG. 18 and FIG. 19 show differential amplifiers used in examples of related art.

The differential amplifier shown in FIG. 18 includes a current mirror circuit including a PMOS transistor P0 and a PMOS transistor P1, a differential stage circuit including an NMOS transistor N0 and an NMOS transistor N1 having gates to which input terminals are connected, and a current source circuit including an NMOS transistor N4, an NMOS transistor N5 having a gate connected to the gate of the NMOS transistor N4, and a bias current source ibp. A voltage of a feedback node fb is inputted to the NMOS transistor N0 of the differential stage circuit, and a reference voltage Vref is inputted to the NMOS transistor N1. In the differential amplifier shown in FIG. 18, a current is generated at the current mirror circuit according to a difference between the voltage of the feedback node fb and the reference voltage Vref inputted to the differential stage circuit. A voltage based on this current is outputted from an output terminal O as an output voltage.

Compared to the differential amplifier shown in FIG. 18, the differential amplifier shown in FIG. 19 further includes an output stage circuit including a PMOS transistor P2 having a gate connected between the PMOS transistor P1 and the NMOS transistor N1, and a bias current source ibn. With the output stage circuit included, the differential amplifier shown in FIG. 19 may output any output voltage.

Thus, in the related art, since one differential amplifier corresponds to one output, to realize multiple inputs and multiple outputs, a plurality of differential amplifiers with identical characteristics are individually provided, which increases the circuit area.

Thus, in the embodiments of the disclosure, it is intended to realize multiple inputs and multiple outputs while suppressing an increase in the circuit area.

### First Embodiment

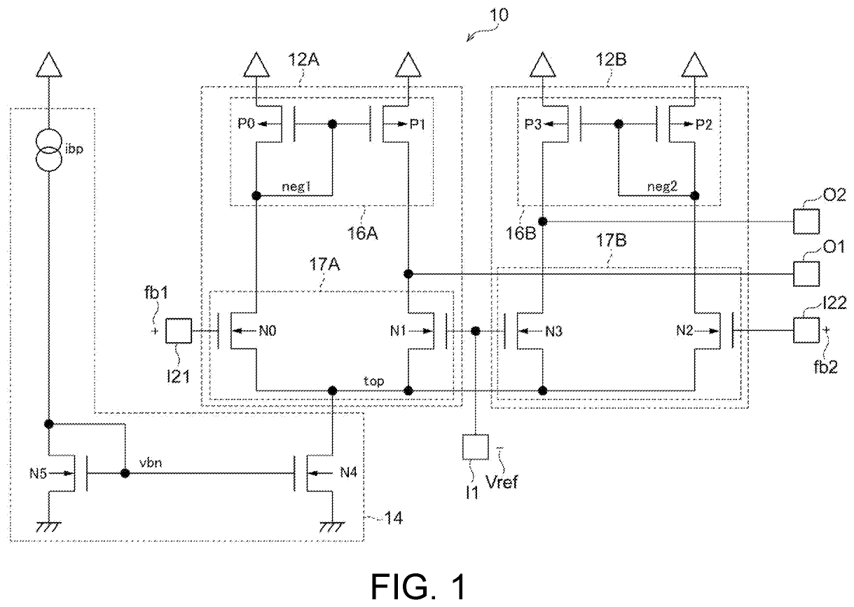

FIG. 1 is a circuit block diagram showing a configuration of a differential amplifier 10 according to a first embodiment of the disclosure.

The differential amplifier 10 includes a first input terminal I1 which is an inverting input terminal, second input terminals I21 and I22 which are non-inverting input terminals, output terminals O1 and O2 corresponding to the second input terminals I21 and I22, differential amplification circuits 12A and 12B provided corresponding to the second input terminals I21 and I22, and a current source circuit 14 connected to the differential amplification circuits 12A and 12B. A reference voltage Vref is inputted to the first input terminal I1, a voltage of a feedback node fb1 is inputted to the second input terminal I21, and a voltage of a feedback node fb2 is inputted to the second input terminal I22.

The differential amplification circuits 12A and 12B are configured to share the current source circuit 14.

The differential amplification circuit 12A outputs, from the output terminal O1, an output voltage corresponding to a combination of the voltage inputted to the first input terminal I1 and the voltage inputted to the second input terminal I21. The differential amplification circuit 12B outputs, from the output terminal O2, an output voltage corresponding to a combination of the voltage inputted to the first input terminal I1 and the voltage inputted to the second input terminal I22.

Specifically, the differential amplification circuit 12A includes a load circuit 16A connected to a power supply potential having a power supply voltage, and a differential stage circuit 17A connected to the first input terminal I1, the second input terminal I21, and the current source circuit 14. The differential amplification circuit 12B includes a load circuit 16B connected to the power supply potential, and a differential stage circuit 17B connected to the first input terminal I1, the second input terminal I22, and the current source circuit 14.

The load circuit 16A is a current mirror circuit including a PMOS transistor P0 and a PMOS transistor P1. The source of the PMOS transistor P0 and the source of the PMOS transistor P1 are connected to the power supply potential, and the drain of the PMOS transistor P0 and the drain of the PMOS transistor P1 are connected to the differential stage circuit 17A. The gate of the PMOS transistor P0 and the gate of the PMOS transistor P1 are connected to a node neg1 at which the drain of the PMOS transistor P0 and the differential stage circuit 17A are connected.

The load circuit 16A is a circuit that serves as a load of the differential stage circuit 17A. The current flowing through the load circuit 16A is determined according to a difference in voltages inputted to the differential stage circuit 17A. Specifically, the current flowing through the PMOS transistor P0 is determined according to the difference in the voltages inputted to the differential stage circuit 17A, and the current flowing through the PMOS transistor P1 is determined according to the current flowing through the PMOS transistor P0.

The differential stage circuit 17A includes an NMOS transistor N1 having a gate to which the first input terminal I1 is connected, and an NMOS transistor N0 having a gate to which the second input terminal I21 is connected. The drain of the NMOS transistor N0 is connected to the drain of the PMOS transistor P0 of the load circuit 16A, and the drain of the NMOS transistor N1 is connected to the drain of the PMOS transistor P1 of the load circuit 16A. The source of the NMOS transistor N0 and the source of the NMOS transistor N1 are connected to the current source circuit 14 via a node top. Further, the differential stage circuit 17A may be said to include a differential pair composed of the NMOS transistor N0 and the NMOS transistor N1 as one pair.

The differential stage circuit 17A is connected to the first input terminal I1 and the second input terminal I21, and is a circuit that receives the voltages inputted to the differential amplification circuit 12A. The differential stage circuit 17A operates according to a difference in the inputted voltages.

The section between the drain of the PMOS transistor P1 and the drain of the NMOS transistor N1 is connected to the output terminal O1.

The load circuit 16B is a current mirror circuit including a PMOS transistor P2 and a PMOS transistor P3. The source of the PMOS transistor P2 and the source of the PMOS transistor P3 are connected to the power supply potential, and the drain of the PMOS transistor P2 and the drain of the PMOS transistor P3 are connected to the differential stage circuit 17B. The gate of the PMOS transistor P2 and the gate of the PMOS transistor P3 are connected to a node neg2 at which the drain of the PMOS transistor P2 and the differential stage circuit 17B are connected.

The load circuit 16B is a circuit that serves as a load of the differential stage circuit 17B. The current flowing through the load circuit 16B is determined according to a difference in voltages inputted to the differential stage circuit 17B. Specifically, the current flowing through the PMOS transistor P2 is determined according to the difference in the voltages inputted to the differential stage circuit 17B, and the current flowing through the PMOS transistor P3 is determined according to the current flowing through the PMOS transistor P2.

The differential stage circuit 17B includes an NMOS transistor N3 having a gate to which the first input terminal I1 is connected, and an NMOS transistor N2 having a gate to which the second input terminal I22 is connected. The drain of the NMOS transistor N3 is connected to the drain of the PMOS transistor P3 of the load circuit 16B, and the drain of the NMOS transistor N2 is connected to the drain of the PMOS transistor P2 of the load circuit 16B. The source of the NMOS transistor N2 and the source of the NMOS transistor N3 are connected to the current source circuit 14 via the node top. Further, the differential stage circuit 17B may be said to include a differential pair composed of the NMOS transistor N3 and the NMOS transistor N2 as one pair.

The differential stage circuit 17B is connected to the first input terminal I1 and the second input terminal I22, and is a circuit that receives voltages inputted to the differential amplification circuit 12B. The differential stage circuit 17B operates according to a difference in the inputted voltages.

The section between the drain of the PMOS transistor P3 and the drain of the NMOS transistor N3 is connected to the output terminal O2.

The current source circuit 14 includes an NMOS transistor N4 and an NMOS transistor N5 having gates connected to each other, and a bias current source ibp. The drain of the NMOS transistor N4 is connected to the differential stage circuit 17A and the differential stage circuit 17B, and the source of the NMOS transistor N4 is connected to a ground potential having a ground voltage. The drain of the NMOS transistor N5, the gate of the NMOS transistor N4, and the gate of the NMOS transistor N5 are connected to a node vbn, and the source of the NMOS transistor N5 is connected to the ground potential. One terminal of the bias current source ibp is connected to the power supply potential, and the other terminal of the bias current source ibp is connected to the drain of the NMOS transistor N5.

The current source circuit 14 is a circuit that supplies a current to the differential amplification circuits 12A and 12B. The NMOS transistor N4 and the NMOS transistor N5 form a current mirror circuit. With this current mirror circuit, it is possible to supply a current generated at a bias current source ibp to the differential amplification circuits 12A and 12B.

Compared to the differential amplifier in the related art of FIG. 18, the differential amplifier 10 in FIG. 1 differs in that the differential amplification circuit 12B and the output terminal O2 are additionally provided. In other words, in the differential amplifier in the related art of FIG. 18, two differential amplifiers are required for two outputs; in contrast, the differential amplifier 10 in FIG. 1 can provide two outputs with one differential amplifier sharing the current source circuit 14. Thus, compared to the differential amplifier in the related art of FIG. 18, it is possible to suppress an increase in the circuit scale in the case where multiple outputs are required.

In the above embodiment, as an example, it has been described that there are one first input terminal, two second input terminals, and two output terminals, but the disclosure is not limited thereto. In the case where there are N (N being 2 or more) second input terminals, N output terminals may be provided. In the case where there are N second input terminals and N output terminals, the quantity of the differential amplification circuit in FIG. 1 becomes N, and the quantity of the differential amplification circuits is determined according to the required quantity of the second input terminals and the output terminals.

In the differential amplifier 10, the differential amplification circuits 12A and 12B operate individually. Specifically, the differential amplification circuit 12A outputs, from the output terminal O1, an output voltage corresponding to a combination of the voltage inputted to the first input terminal I1 and the voltage inputted to the second input terminal I21. The differential amplification circuit 12B outputs, from the output terminal O2, an output voltage corresponding to a combination of the voltage inputted to the first input terminal I1 and the voltage inputted to the second input terminal I22.

In the differential amplification circuit 12A, a current is generated at the load circuit 16A according to a difference between the reference voltage Vref and the voltage of the feedback node fb1 inputted to the differential stage circuit 17A. A voltage based on this current is outputted from the output terminal O1 as an output voltage. Similarly, in the differential amplification circuit 12B, a current is generated at the load circuit 16B according to a difference between the reference voltage Vref and the voltage of the feedback node fb2 inputted to the differential stage circuit 17B. A voltage based on this current is outputted from the output terminal O2 as an output voltage.

As described above, according to the differential amplifier 10 of the first embodiment of the disclosure, each of the differential amplification circuits outputs, from the corresponding output terminal, an output voltage corresponding to a combination of the voltage inputted to the first input terminal and the voltage inputted to the corresponding second input terminal. Thus, by realizing multiple inputs and multiple outputs, it is possible to suppress an increase in the circuit scale.

In the above embodiment, as an example, it has been described that the first input terminal is an inverting input terminal, and the plurality of second input terminals are non-inverting input terminals, but the disclosure is not limited thereto. The first input terminal may also be a non-inverting input terminal, and the plurality of second input terminals may also be inverting input terminals.

### Second Embodiment

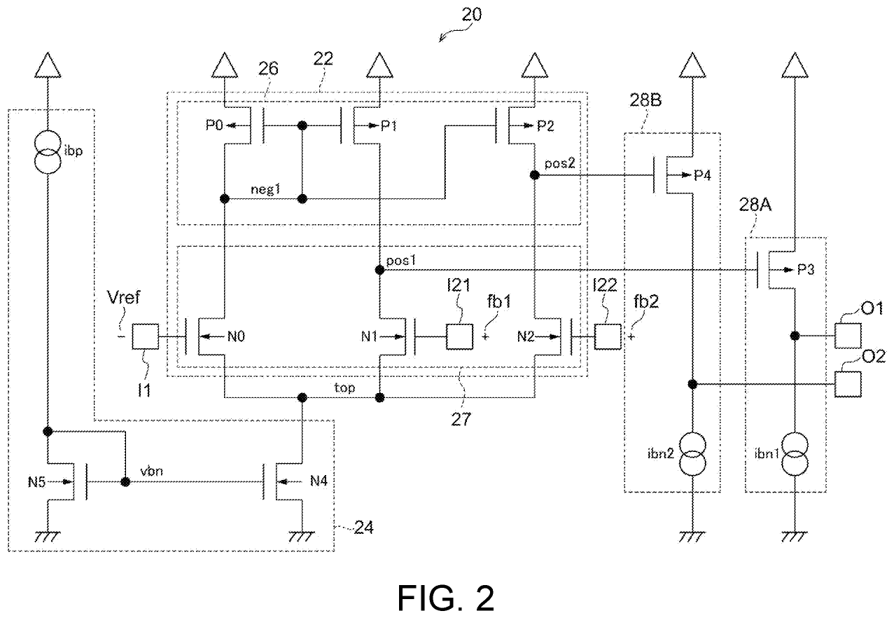

FIG. 2 is a circuit block diagram showing a configuration of a differential amplifier 20 according to a second embodiment of the disclosure.

The differential amplifier 20 includes a first input terminal I1 which is an inverting input terminal, second input terminals I21 and I22 which are non-inverting input terminals, output terminals O1 and O2 corresponding to the second input terminals I21 and I22, a differential amplification circuit 22, output stage circuits 28A and 28B provided corresponding to the output terminals O1 and O2, and a current source circuit 24 connected to the differential amplification circuit 22. A reference voltage Vref is inputted to the first input terminal I1, a voltage of a feedback node fb1 is inputted to the second input terminal I21, and a voltage of a feedback node fb2 is inputted to the second input terminal I22.

The differential amplification circuit 22 is configured to share a partial circuit corresponding to the second input terminals I21 and I22 and connected to the first input terminal I1. In other words, the differential amplification circuit 22 may also be said to be a plurality of differential amplification circuits sharing a partial circuit connected to the first input terminal I1. Furthermore, the differential amplification circuit 22 is configured to share the current source circuit 24.

The differential amplification circuit 22 outputs, from the output terminal O1, an output voltage corresponding to a combination of the voltage inputted to the first input terminal I1 and the voltage inputted to the second input terminal I21. The differential amplification circuit 22 outputs, from the output terminal O2, an output voltage corresponding to a combination of the voltage inputted to the first input terminal I1 and the voltage inputted to the second input terminal I22.

Specifically, the differential amplification circuit 22 includes a load circuit 26 connected to a power supply potential having a power supply voltage, and a differential stage circuit 27 connected to the first input terminal I1, the second input terminals I21 and I22, and the current source circuit 24.

The load circuit 26 is equivalent to two current mirror circuits sharing a PMOS transistor P0, and includes a PMOS transistor P0, a PMOS transistor P1, and a PMOS transistor P2. The source of the PMOS transistor P0, the source of the PMOS transistor P1, and the source of the PMOS transistor P2 are connected to the power supply potential, and the drain of the PMOS transistor P0, the drain of the PMOS transistor P1, and the drain of the PMOS transistor P2 are connected to the differential stage circuit 27. The gate of the PMOS transistor P0, the gate of the PMOS transistor P1, and the gate of the PMOS transistor P2 are connected to a node neg1 at which the drain of the PMOS transistor P0 and the differential stage circuit 27 are connected.

The load circuit 26 is a circuit that serves as a load of the differential stage circuit 27. The current flowing through the load circuit 26 is determined according to a difference in voltages inputted to the differential stage circuit 27. Specifically, the current flowing through the PMOS transistor P0 is determined according to the difference in the voltages inputted to the differential stage circuit 27, and the currents flowing through the PMOS transistor P1 and the PMOS transistor P2 are determined according to the current flowing through the PMOS transistor P0.

The differential stage circuit 27 is equivalent to two differential stage circuits sharing an NMOS transistor N0, and includes an NMOS transistor N0 having a gate to which the first input terminal I1 is connected, an NMOS transistor N1 having a gate to which the second input terminal I21 is connected, and an NMOS transistor N2 having a gate to which the second input terminal I22 is connected. The drain of the NMOS transistor N0 is connected to the drain of the PMOS transistor P0 of the load circuit 26, the drain of the NMOS transistor N1 is connected to the drain of the PMOS transistor P1 of the load circuit 26, and the drain of the NMOS transistor N2 is connected to the drain of the PMOS transistor P2 of the load circuit 26. The source of the NMOS transistor N0, the source of the NMOS transistor N1, and the source of the NMOS transistor N2 are connected to the current source circuit 24 via a node top. Further, the differential stage circuit 27 may be said to include a first differential pair composed of the NMOS transistor N0 and the NMOS transistor N1 as one pair, and a second differential pair composed of the NMOS transistor N0 and the NMOS transistor N2 as one pair.

The differential stage circuit 27 is connected to the first input terminal I1 and the second input terminals I21 and I22, and is a circuit that receives voltages inputted to the differential amplification circuit 22. The differential stage circuit 27 operates according to a difference in the inputted voltages.

A node pos1, at which the drain of the PMOS transistor P1 and the drain of the NMOS transistor N1 are connected, is connected to the output terminal O1 via the output stage circuit 28A. A node pos2, at which the drain of the PMOS transistor P2 and the drain of the NMOS transistor N2 are connected, is connected to the output terminal O2 via the output stage circuit 28B.

The current source circuit 24 includes an NMOS transistor N4 and an NMOS transistor N5 having gates connected to each other, and a bias current source ibp. The drain of the NMOS transistor N4 is connected to the differential stage circuit 27, and the source of the NMOS transistor N4 is connected to a ground potential having a ground voltage. The drain of the NMOS transistor N5, the gate of the NMOS transistor N4, and the gate of the NMOS transistor N5 are connected to a node vbn, and the source of the NMOS transistor N5 is connected to the ground potential. One terminal of the bias current source ibp is connected to the power supply potential, and the other terminal of the bias current source ibp is connected to the drain of the NMOS transistor N5.

The current source circuit 24 is a circuit that supplies a current to the differential amplification circuit 22. The NMOS transistor N4 and the NMOS transistor N5 form a current mirror circuit. With this current mirror circuit, it is possible to supply a current generated at the bias current source ibp to the differential amplification circuit 22.

The output stage circuit 28A includes a PMOS transistor P3 having a gate connected to the node pos1 between the PMOS transistor P1 and the NMOS transistor N1, and a bias current source ibn1. The source of the PMOS transistor P3 is connected to the power supply potential, and the drain of the PMOS transistor P3 is connected to the bias current source ibn1. One terminal of the bias current source ibn1 is connected to the drain of the PMOS transistor P3, and the other terminal of the bias current source ibn1 is connected to the ground potential. The section between the PMOS transistor P3 and the bias current source ibn1 is connected to the output terminal O1.

The output stage circuit 28B includes a PMOS transistor P4 having a gate connected to the node pos2 between the PMOS transistor P2 and the NMOS transistor N2, and a bias current source ibn2. The source of the PMOS transistor P4 is connected to the power supply potential, and the drain of the PMOS transistor P4 is connected to the bias current source ibn2. One terminal of the bias current source ibn2 is connected to the drain of the PMOS transistor P4, and the other terminal of the bias current source ibn2 is connected to the ground potential. The section between the PMOS transistor P4 and the bias current source ibn2 is connected to the output terminal O2.

The output stage circuit 28A and the output stage circuit 28B are circuits for supplying a desired voltage. By providing the output stage circuit, it is possible to change the set values of the PMOS transistor and the bias current source that form the output stage circuit to adjust the output voltage.

Compared to the differential amplifier in the related art of FIG. 19, the differential amplifier 20 in FIG. 2 differs in that the PMOS transistor P2, the NMOS transistor N2, the output stage circuit 28A, and the output terminal O2 are additionally provided. In other words, two differential amplifiers are required for two outputs in the conventional differential amplifier in FIG. 19; in contrast, the differential amplifier 20 in FIG. 2 can provide two outputs with one differential amplifier sharing the current source circuit 24, and the PMOS transistor P0 of the load circuit 26 and the NMOS transistor N0 of the differential stage circuit 27, which are a partial circuit connected to the first input terminal I1. Thus, compared to the differential amplifier in the related art of FIG. 19, it is possible to suppress an increase in the circuit scale in the case where multiple outputs are required.

In the above embodiment, as an example, it has been described that there are one first input terminal, two second input terminals, and two output terminals, but the disclosure is not limited thereto. In the case where there are N (N being 2 or more) second input terminals, there may be N output terminals. In the case where there are N second input terminals and N output terminals, the quantity of a part of the differential stage circuit connected to the second input terminal and a part of the load circuit connected to the part of the differential stage circuit in FIG. 2 becomes N, and the quantity of the part of the differential stage circuit connected to the second input terminal and the part of the load circuit connected to the part of the differential stage circuit is determined according to the required quantity of the second input terminals and the output terminals.

In the differential amplifier 20, the differential amplification circuits of the differential amplification circuit 22 that share the partial circuit connected to the first input terminal I1 operate individually. Specifically, the differential amplification circuit 22 outputs, from the output terminal O1 via the output stage circuit 28A, an output voltage corresponding to a combination of the voltage inputted to the first input terminal I1 and the voltage inputted to the second input terminal I21. The differential amplification circuit 22 outputs, from the output terminal O2 via the output stage circuit 28B, an output voltage corresponding to a combination of the voltage inputted to the first input terminal I1 and the voltage inputted to the second input terminal I22.

In the differential amplification circuit 22, a current is generated at the PMOS transistor P0 and the PMOS transistor P1 of the load circuit 26 according to a difference between the reference voltage Vref and the voltage of the feedback node fb1 respectively inputted to the NMOS transistor N0 and the NMOS transistor N1 of the differential stage circuit 27. A voltage based on this current is outputted from the output terminal O1 via the output stage circuit 28A as an output voltage. Similarly, in the case of the NMOS transistor N0 and the NMOS transistor N2 of the differential stage circuit 27, a current is generated at the PMOS transistor P0 and the PMOS transistor P2 of the load circuit 26 according to a difference between the reference voltage Vref and the voltage of the feedback node fb2 respectively inputted to the NMOS transistor N0 and the NMOS transistor N2 of the differential stage circuit 27. A voltage based on this current is outputted from the output terminal O2 via the output stage circuit 28B as an output voltage.

As described above, according to the differential amplifier 20 of the second embodiment of the disclosure, each of the differential amplification circuits sharing the partial circuit connected to the first input terminal outputs, from the corresponding output terminal, an output voltage corresponding to a combination of the voltage inputted to the first input terminal and the voltage inputted to the corresponding second input terminal. Thus, by realizing multiple inputs and multiple outputs, it is possible to suppress an increase in the circuit scale.

In the above embodiment, as an example, it has been described that the first input terminal is an inverting input terminal, and the plurality of second input terminals are non-inverting input terminals, but the disclosure is not limited thereto. The first input terminal may also be a non-inverting input terminal, and the plurality of second input terminals may also be inverting input terminals.

### Third Embodiment

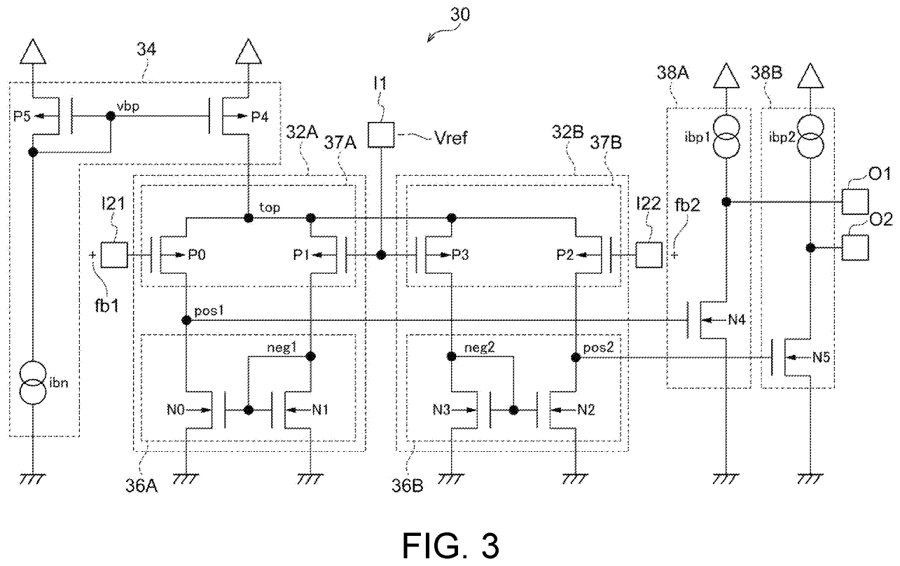

FIG. 3 is a circuit block diagram showing a configuration of a differential amplifier 30 according to a third embodiment of the disclosure. The differential amplifier 30 according to the third embodiment of the disclosure is configured by inverting the polarity of the differential amplifier 10 according to the first embodiment. Furthermore, the differential amplifier 30 according to the third embodiment of the disclosure further includes output stage circuits.

The differential amplifier 30 includes a first input terminal I1 which is an inverting input terminal, second input terminals I21 and I22 which are non-inverting input terminals, output terminals O1 and O2 corresponding to the second input terminals I21 and I22, differential amplification circuits 32A and 32B provided corresponding to the second input terminals I21 and I22, a current source circuit 34 connected to the differential amplification circuits 32A and 32B, and output stage circuits 38A and 38B provided corresponding to the output terminals O1 and O2. A reference voltage Vref is inputted to the first input terminal I1, a voltage of a feedback node fb1 is inputted to the second input terminal I21, and a voltage of a feedback node fb2 is inputted to the second input terminal I22.

The differential amplification circuits 32A and 32B are configured to share the current source circuit 34.

The differential amplification circuit 32A outputs, from the output terminal O1 via the output stage circuit 38A, an output voltage corresponding to a combination of the voltage inputted to the first input terminal I1 and the voltage inputted to the second input terminal I21. The differential amplification circuit 32B outputs, from the output terminal O2 via the output stage circuit 38B, an output voltage corresponding to a combination of the voltage inputted to the first input terminal I1 and the voltage inputted to the second input terminal I22.

Specifically, the differential amplification circuit 32A includes a load circuit 36A connected to a ground potential, and a differential stage circuit 37A connected to the first input terminal I1, the second input terminal I21, and the current source circuit 34. The differential amplification circuit 32B includes a load circuit 36B connected to the ground potential, and a differential stage circuit 37B connected to the first input terminal I1, the second input terminal I22, and the current source circuit 34.

The load circuit 36A is a current mirror circuit including an NMOS transistor N0 and an NMOS transistor N1. The source of the NMOS transistor N0 and the source of the NMOS transistor N1 are connected to the ground potential, and the drain of the NMOS transistor N0 and the drain of the NMOS transistor N1 are connected to the differential stage circuit 37A. The gate of the NMOS transistor N0 and the gate of the NMOS transistor N1 are connected to a node neg1 at which the drain of the NMOS transistor N1 and the differential stage circuit 37A are connected.

The load circuit 36A is a circuit that serves as a load of the differential stage circuit 37A. The current flowing through the load circuit 36A is determined according to a difference in voltages inputted to the differential stage circuit 37A. Specifically, the current flowing through the NMOS transistor N1 is determined according to the difference in the voltages inputted to the differential stage circuit 37A, and the current flowing through the NMOS transistor N0 is determined according to the current flowing through the NMOS transistor N1.

The differential stage circuit 37A includes a PMOS transistor P1 having a gate to which the first input terminal I1 is connected, and a PMOS transistor P0 having a gate to which the second input terminal I21 is connected. The drain of the PMOS transistor P0 is connected to the drain of the NMOS transistor N0 of the load circuit 36A, and the drain of the PMOS transistor P1 is connected to the drain of the NMOS transistor N1 of the load circuit 36A. The source of the PMOS transistor P0 and the source of the PMOS transistor P1 are connected to the current source circuit 34 via a node top. Further, the differential stage circuit 37A may be said to include a differential pair composed of the PMOS transistor P0 and the PMOS transistor P1 as one pair.

The differential stage circuit 37A is connected to the first input terminal I1 and the second input terminal I21, and is a circuit that receives voltages inputted to the differential amplification circuit 32A. The differential stage circuit 37A operates according to a difference in the inputted voltages.

A node pos1, at which the drain of the NMOS transistor N0 and the drain of the PMOS transistor P0 are connected, is connected to the output terminal O1 via the output stage circuit 38A.

The load circuit 36B is a current mirror circuit including an NMOS transistor N2 and an NMOS transistor N3. The source of the NMOS transistor N2 and the source of the NMOS transistor N3 are connected to the ground potential, and the drain of the NMOS transistor N2 and the drain of the NMOS transistor N3 are connected to the differential stage circuit 37B. The gate of the NMOS transistor N2 and the gate of the NMOS transistor N3 are connected to a node neg2 at which the drain of the NMOS transistor N3 and the differential stage circuit 37B are connected.

The load circuit 36B is a circuit that serves as a load of the differential stage circuit 37B. The current flowing through the load circuit 36B is determined according to a difference in voltages inputted to the differential stage circuit 37B. Specifically, the current flowing through the NMOS transistor N3 is determined according to a difference in voltages inputted to the differential stage circuit 37B, and the current flowing through the NMOS transistor N2 is determined according to the current flowing through the NMOS transistor N3.

The differential stage circuit 37B includes a PMOS transistor P3 having a gate to which the first input terminal I1 is connected, and a PMOS transistor P2 having a gate to which the second input terminal I22 is connected. The drain of the PMOS transistor P3 is connected to the drain of the NMOS transistor N3 of the load circuit 36B, and the drain of the PMOS transistor P2 is connected to the drain of the NMOS transistor N2 of the load circuit 36B. The source of the PMOS transistor P2 and the source of the PMOS transistor P3 are connected to the current source circuit 34 via the node top. Further, the differential stage circuit 37B may be said to include a differential pair composed of the PMOS transistor P3 and the PMOS transistor P2 as one pair.

The differential stage circuit 37B is connected to the first input terminal I1 and the second input terminal I22, and is a circuit that receives voltages inputted to the differential amplification circuit 32B. The differential stage circuit 37B operates according to a difference in the inputted voltages.

A node pos2, at which the drain of the NMOS transistor N2 and the drain of the PMOS transistor P2 are connected, is connected to the output terminal O2 via the output stage circuit 38B.

The current source circuit 34 includes a PMOS transistor P4 and a PMOS transistor P5 having gates connected to each other, and a bias current source ibn. The drain of the PMOS transistor P4 is connected to the differential stage circuit 37A and the differential stage circuit 37B, and the source of the PMOS transistor P4 is connected to a power supply potential having a power supply voltage. The drain of the PMOS transistor P5, the gate of the PMOS transistor P4, and the gate of the PMOS transistor P5 are connected to a node vbp, and the source of the PMOS transistor P5 is connected to the power supply potential. One terminal of the bias current source ibn is connected to the ground potential, and the other terminal of the bias current source ibn is connected to the drain of the PMOS transistor P5.

The current source circuit 34 is a circuit that supplies a current to the differential amplification circuits 32A and 32B. The PMOS transistor P4 and the PMOS transistor P5 form a current mirror circuit. With this current mirror circuit, it is possible to supply a current generated at the bias current source ibn to the differential amplification circuits 32A and 32B.

The output stage circuit 38A includes an NMOS transistor N4 having a gate connected to the node pos1 at which the PMOS transistor P0 and the NMOS transistor N0 are connected, and a bias current source ibp1. The source of the NMOS transistor N4 is connected to the ground potential, and the drain of the NMOS transistor N4 is connected to the bias current source ibp1. One terminal of the bias current source ibp1 is connected to the drain of the NMOS transistor N4, and the other terminal of the bias current source ibp1 is connected to the power supply potential. The section between the NMOS transistor N4 and the bias current source ibp1 is connected to the output terminal O1.

The output stage circuit 38B includes an NMOS transistor N5 having a gate connected to the node pos2 at which the PMOS transistor P2 and the NMOS transistor N2 are connected, and a bias current source ibp2. The source of the NMOS transistor N5 is connected to the ground potential, and the drain of the NMOS transistor N5 is connected to the bias current source ibp2. One terminal of the bias current source ibp2 is connected to the drain of the NMOS transistor N5, and the other terminal of the bias current source ibp2 is connected to the power supply potential. The section between the NMOS transistor N5 and the bias current source ibp2 is connected to the output terminal O2.

The output stage circuit 38A and the output stage circuit 38B are circuits for supplying a desired voltage. By providing the output stage circuit, it is possible to change the set values of the NMOS transistor and the bias current source that form the output stage circuit to adjust the output voltage.

Compared to a differential amplifier configured by inverting the polarity of the differential amplifier in the related art of FIG. 19, the differential amplifier 30 in FIG. 3 differs in that the differential amplification circuit 32B, the output stage circuit 38B, and the output terminal O2 are provided. In other words, two differential amplifiers are required for two outputs in the differential amplifier configured by inverting the polarity of the differential amplifier in the related art of FIG. 19; in contrast, the differential amplifier 30 in FIG. 3 can provide two outputs with one differential amplifier sharing the current source circuit 34. Thus, compared to the differential amplifier configured by inverting the polarity of the differential amplifier in the related art of FIG. 19, it is possible to suppress an increase in the circuit scale in the case where multiple outputs are required.

In the above embodiment, as an example, it has described that there are one first input terminal, two second input terminals, and two output terminals, but the disclosure is not limited thereto. In the case where there are N (N being 2 or more) second input terminals, N output terminals may be provided. In the case where there are N second input terminals and N output terminals, the quantity of the differential amplification circuits in FIG. 3 becomes N, and the quantity of the differential amplification circuits is determined according to the required quantity of the second input terminals and the output terminals.

In the differential amplifier 30, the differential amplification circuits 32A and 32B operate individually. Specifically, the differential amplification circuit 32A outputs, from the output terminal O1 via the output stage circuit 38A, an output voltage corresponding to a combination of the voltage inputted to the first input terminal I1 and the voltage inputted to the second input terminal I21. The differential amplification circuit 32B outputs, from the output terminal O2 via the output stage circuit 38B, an output voltage corresponding to a combination of the voltage inputted to the first input terminal I1 and the voltage inputted to the second input terminal I22.

In the differential amplification circuit 32A, a current is generated at the load circuit 36A according to a difference between the reference voltage Vref and the voltage of the feedback node fb1 inputted to the differential stage circuit 37A. A voltage based on this current is outputted from output terminal O1 as an output voltage. Similarly, in the differential amplification circuit 32B, a current is generated at the load circuit 36B according to a difference between the reference voltage Vref and the voltage of the feedback node fb2 inputted to the differential stage circuit 37B. A voltage based on this current is outputted from the output terminal O2 as an output voltage.

As described above, according to the differential amplifier 30 of the third embodiment of the disclosure, each of the differential amplification circuits outputs, from the corresponding output terminal, an output voltage corresponding to a combination of the voltage inputted to the first input terminal and the voltage inputted to the corresponding second input terminal. Thus, by realizing multiple inputs and multiple outputs, it is possible to suppress an increase in the circuit scale.

In the above embodiment, as an example, it has been described that the first input terminal is an inverting input terminal, and the plurality of second input terminals are non-inverting input terminals, but the disclosure is not limited thereto. The first input terminal may also be a non-inverting input terminal, and the plurality of second input terminals may also be inverting input terminals.

### Fourth Embodiment

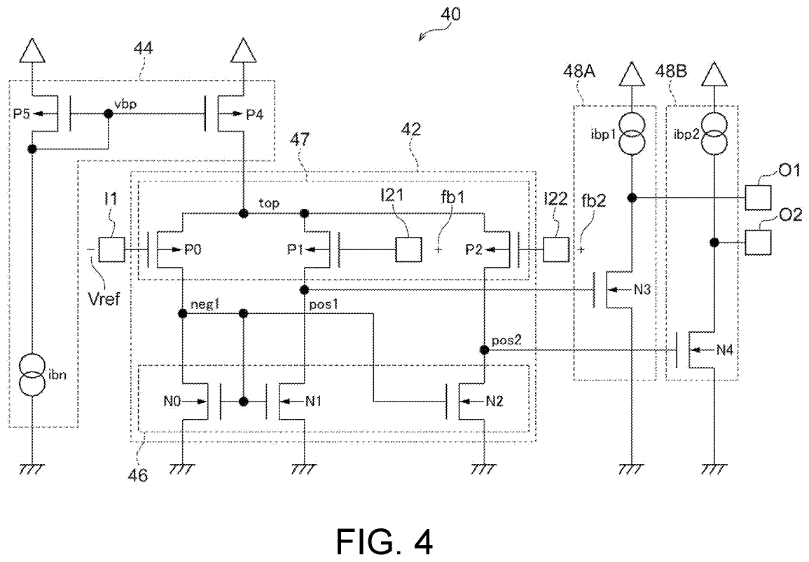

FIG. 4 is a circuit block diagram showing a configuration of a differential amplifier 40 according to a fourth embodiment of the disclosure. The differential amplifier 40 according to the fourth embodiment of the disclosure is configured by inverting the polarity of the differential amplifier 20 according to the second embodiment.

The differential amplifier 40 includes a first input terminal I1 which is an inverting input terminal, second input terminals I21 and I22 which are non-inverting input terminals, output terminals O1 and O2 corresponding to the second input terminals I21 and I22, a differential amplification circuit 42, output stage circuits 48A and 48B provided corresponding to the output terminals O1 and O2, and a current source circuit 44 connected to the differential amplification circuit 42. A reference voltage Vref is inputted to the first input terminal I1, a voltage of a feedback node fb1 is inputted to the second input terminal I21, and a voltage of a feedback node fb2 is inputted to the second input terminal I22.

The differential amplification circuit 42 is configured to share a partial circuit corresponding to the second input terminals I21 and I22 and connected to the first input terminal I1. In other words, the differential amplification circuit 42 may also be said to be a plurality of differential amplification circuits sharing a partial circuit connected to the first input terminal I1. Furthermore, the differential amplification circuit 42 is configured to share the current source circuit 44.

The differential amplification circuit 42 outputs, from the output terminal O1 via the output stage circuit 48A, an output voltage corresponding to a combination of the voltage inputted to the first input terminal I1 and the voltage inputted to the second input terminal I21. The differential amplification circuit 42 outputs, from the output terminal O2 via the output stage circuit 48B, an output voltage corresponding to a combination of the voltage inputted to the first input terminal I1 and the voltage inputted to the second input terminal I22.

Specifically, the differential amplification circuit 42 includes a load circuit 46 connected to a ground potential, and a differential stage circuit 47 connected to the first input terminal I1, the second input terminals I21 and I22, and the current source circuit 44.

The load circuit 46 is equivalent to two current mirror circuits sharing an NMOS transistor N0, and includes an NMOS transistor N0, an NMOS transistor N1, and an NMOS transistor N2. The source of the NMOS transistor N0, the source of the NMOS transistor N1, and the source of the NMOS transistor N2 are connected to the ground potential, and the drain of the NMOS transistor N0, the drain of the NMOS transistor N1, and the drain of the NMOS transistor N2 are connected to the differential stage circuit 47. The gate of the NMOS transistor NO, the gate of the NMOS transistor N1, and the gate of the NMOS transistor N2 are connected to a node neg1 at which the drain of the NMOS transistor N0 and the differential stage circuit 47 are connected.

The load circuit 46 is a circuit that serves as a load of the differential stage circuit 47. The current flowing through the load circuit 46 is determined according to a difference in voltages inputted to the differential stage circuit 47. Specifically, the current flowing through the NMOS transistor N0 is determined according to the difference in the voltages inputted to the differential stage circuit 47, and the currents flowing through the NMOS transistor N1 and the NMOS transistor N2 are determined according to the current flowing through the NMOS transistor N0.

The differential stage circuit 47 is equivalent to two differential stage circuits sharing a PMOS transistor P0, and includes a PMOS transistor P0 having a gate to which the first input terminal I1 is connected, a PMOS transistor P1 having a gate to which the second input terminal I21 is connected, and a PMOS transistor P2 having a gate to which the second input terminal I22 is connected. The drain of the PMOS transistor P0 is connected to the drain of the NMOS transistor N0 of the load circuit 46, the drain of the PMOS transistor P1 is connected to the drain of the NMOS transistor N1 of the load circuit 46, and the drain of the PMOS transistor P2 is connected to the drain of the NMOS transistor N2 of the load circuit 46. The source of the PMOS transistor P0, the source of the PMOS transistor P1, and the source of the PMOS transistor P2 are connected to the current source circuit 44 via a node top. Further, the differential stage circuit 47 may be said to include a first differential pair composed of the PMOS transistor P0 and the PMOS transistor P1 as one pair, and a second differential pair composed of the PMOS transistor P0 and the PMOS transistor P2 as one pair.

The differential stage circuit 47 is connected to the first input terminal I1 and the second input terminals I21 and I22, and is a circuit that receives voltages inputted to the differential amplification circuit 42. The differential stage circuit 47 operates according to a difference in the inputted voltages.

A node pos1, at which the drain of the PMOS transistor P1 and the drain of the NMOS transistor N1 are connected, is connected to the output terminal O1 via the output stage circuit 48A. A node pos2, at which the drain of the PMOS transistor P2 and the drain of the NMOS transistor N2 are connected, is connected to the output terminal O2 via the output stage circuit 48B.

The current source circuit 44 includes a PMOS transistor P4 and a PMOS transistor P5 having gates connected to each other, and a bias current source ibn. The drain of the PMOS transistor P4 is connected to the differential stage circuit 47, and the source of the PMOS transistor P4 is connected to a power supply potential having a power supply voltage. The drain of the PMOS transistor P5, the gate of the PMOS transistor P4, and the gate of the PMOS transistor P5 are connected to a node vbp, and the source of the PMOS transistor P5 is connected to the power supply potential. One terminal of the bias current source ibn is connected to the ground potential, and the other terminal of the bias current source ibn is connected to the drain of the PMOS transistor P5.

The current source circuit 44 is a circuit that supplies a current to the differential amplification circuit 42. The PMOS transistor P4 and the PMOS transistor P5 form a current mirror circuit. With this current mirror circuit, it is possible to supply a current generated at the bias current source ibn to the differential amplification circuit 42.

The output stage circuit 48A includes an NMOS transistor N3 having a gate connected to the node pos1 at which the NMOS transistor N1 and the PMOS transistor P1 are connected, and a bias current source ibp1. The source of the NMOS transistor N3 is connected to the ground potential, and the drain of the NMOS transistor N3 is connected to the bias current source ibp1. One terminal of the bias current source ibp1 is connected to the drain of the NMOS transistor N3, and the other terminal of the bias current source ibp1 is connected to the power supply potential. The section between the NMOS transistor N3 and the bias current source ibp1 is connected to the output terminal O1.

The output stage circuit 48B includes an NMOS transistor N4 having a gate connected to the node pos2 at which the NMOS transistor N2 and the PMOS transistor P2 are connected, and a bias current source ibp2. The source of the NMOS transistor N4 is connected to the ground potential, and the drain of the NMOS transistor N4 is connected to the bias current source ibp2. One terminal of the bias current source ibp2 is connected to the drain of the NMOS transistor N4, and the other terminal of the bias current source ibp2 is connected to the power supply potential. The section between the NMOS transistor N4 and the bias current source ibp2 is connected to the output terminal O2.

The output stage circuit 48A and the output stage circuit 48B are circuits for supplying a desired voltage. By providing the output stage circuit, it is possible to change the set values of the NMOS transistor and the bias current source that form the output stage circuit to adjust the output voltage.

Compared to a differential amplifier configured by inverting the polarity of the differential amplifier in the related art of FIG. 19, the differential amplifier 40 in FIG. 4 differs in that the NMOS transistor N2, the PMOS transistor P2, the output stage circuit 48B, and the output terminal O2 are additionally provided. In other words, two differential amplifiers are required for two outputs in the differential amplifier configured by inverting the polarity of the conventional differential amplifier in FIG. 19; in contrast, the differential amplifier 40 in FIG. 4 can provide two outputs with one differential amplifier sharing the current source circuit 44, and the NMOS transistor N0 of the load circuit 46 and the PMOS transistor P0 of the differential stage circuit 47, which are the partial circuit connected to the first input terminal I1. Thus, compared to the differential amplifier configured by inverting the polarity of the differential amplifier in the related art of FIG. 19, it is possible to suppress an increase in the circuit scale in the case where multiple outputs are required.

In the above embodiment, as an example, it has been described that there are one first input terminal, two second input terminals, and two output terminals, but the disclosure not limited thereto. In the case where there are N (N being 2 or more) second input terminals, there may be N output terminals. In the case where there are N second input terminals and N output terminals, the quantity of a part of the differential stage circuit connected to the second input terminal and a part of the load circuit connected to the part of the differential stage circuit in FIG. 4 becomes N, and the quantity of the part of the differential stage circuit connected to the second input terminal and the part of the load circuit connected to the differential stage circuit is determined according to the required quantity of the second input terminals and the output terminals.

In the differential amplifier 40, the differential amplification circuits of the differential amplification circuit 42 that share the partial circuit connected to the first input terminal I1 operate individually. Specifically, the differential amplification circuit 42 outputs, from the output terminal O1 via the output stage circuit 48A, an output voltage corresponding to a combination of the voltage inputted to the first input terminal I1 and the voltage inputted to the second input terminal I21. The differential amplification circuit 42 outputs, from the output terminal O2 via the output stage circuit 48B, an output voltage corresponding to a combination of the voltage inputted to the first input terminal I1 and the voltage inputted to the second input terminal I22.

In the differential amplification circuit 42, a current is generated at the NMOS transistor N0 and the NMOS transistor N1 of the load circuit 46 according to a difference between the reference voltage Vref and the voltage of the feedback node fb1 respectively inputted to the PMOS transistor P0 and the PMOS transistor P1 of the differential stage circuit 47. A voltage based on this current is outputted from the output terminal O1 via the output stage circuit 48A as an output voltage. Similarly, in the case of the PMOS transistor P0 and the PMOS transistor P2 of the differential stage circuit 47, a current is generated at the NMOS transistor N0 and the NMOS transistor N2 of the load circuit 46 according to a difference between the reference voltage Vref and the voltage of the feedback node fb2 respectively inputted to the PMOS transistor P0 and the PMOS transistor P2 of the differential stage circuit 47. A voltage based on this current is outputted from the output terminal O2 via the output stage circuit 48B as an output voltage.

As described above, according to the differential amplifier 40 of the fourth embodiment of the disclosure, each of the differential amplification circuits sharing the partial circuit connected to the first input terminal outputs, from the corresponding output terminal, an output voltage corresponding to a combination of the voltage inputted to the first input terminal and the voltage inputted to the corresponding second input terminal. Thus, by realizing multiple inputs and multiple outputs with one differential amplifier, it is possible to suppress an increase in the circuit scale.

In the above embodiment, as an example, it has been described that the first input terminal is an inverting input terminal, and the plurality of second input terminals are non-inverting input terminals, but the disclosure is not limited thereto. The first input terminal may also be a non-inverting input terminal, and the plurality of second input terminals may also be inverting input terminals.

### Fifth Embodiment

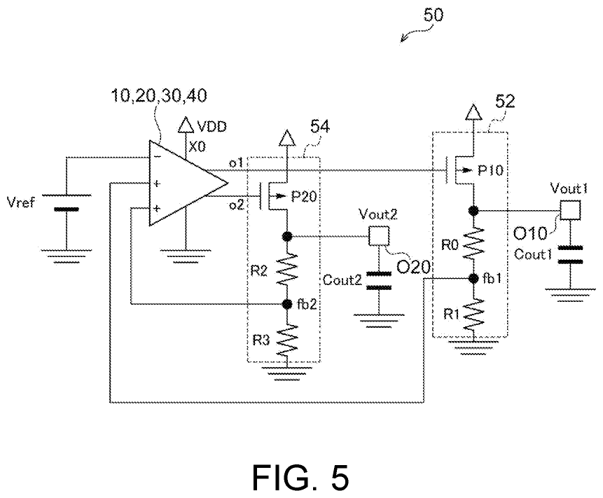

FIG. 5 is a circuit block diagram showing a configuration of a regulator 50 according to a fifth embodiment of the disclosure.

As an example, the regulator 50 will be described to include the differential amplifier 10 described in the first embodiment. A reference voltage Vref is applied to the first input terminal I1 of the differential amplifier 10. The output terminal O1 of the differential amplifier 10 is connected to the gate of a PMOS transistor P10. The regulator 50 includes a series circuit 52 including the PMOS transistor P10 and feedback resistors R0 and R1.

The source of the PMOS transistor P10 is connected to a power supply potential having a power supply voltage, and the drain of the PMOS transistor P10 is connected to the feedback resistor R0. One terminal of the feedback resistor R0 is connected to the drain of the PMOS transistor P10, and the other terminal of the feedback resistor R0 is connected to the feedback resistor R1. One terminal of the feedback resistor R1 is connected to the other terminal of the feedback resistor R0, and the other terminal of the feedback resistor R1 is connected to a ground potential having a ground voltage.

The section between the drain of the PMOS transistor P10 and the one terminal of the feedback resistor R0 is connected to an output terminal O10. The output terminal O10 is connected to the ground potential via a capacitor Cout1. A feedback node fb1 between the feedback resistors R0 and R1 is connected to the second input terminal I21 of the differential amplifier 10.

The output terminal O2 of the differential amplifier 10 is connected to the gate of a PMOS transistor P20. The regulator 50 includes a series circuit 54 including the PMOS transistor P20 and feedback resistors R2 and R3.

The source of the PMOS transistor P20 is connected to the power supply potential, and the drain of the PMOS transistor P20 is connected to the feedback resistor R2. One terminal of the feedback resistor R2 is connected to the drain of the PMOS transistor P20, and the other terminal of the feedback resistor R2 is connected to the feedback resistor R3. One terminal of the feedback resistor R3 is connected to the other terminal of the feedback resistor R2, and the other terminal of the feedback resistor R3 is connected to the ground potential.

The section between the drain of the PMOS transistor P20 and the one terminal of the feedback resistor R2 is connected to an output terminal O20. The output terminal O20 is connected to the ground potential via a capacitor Cout2. A feedback node fb2 between the feedback resistors R2 and R3 is connected to the second input terminal I22 of the differential amplifier 10.

The regulator 50 inputs the reference voltage Vref to the first input terminal I1, which is a non-inverting terminal of the differential amplifier 10, inputs the voltage of the feedback node fb1 to the second input terminal I21, which is an inverting terminal of the differential amplifier 10, and keeps an output voltage Vout1 of the output terminal O10 constant.

Further, the regulator 50 inputs the reference voltage Vref to the first input terminal I1, which is the non-inverting terminal of the differential amplifier 10, inputs the voltage of the feedback node fb2 to the second input terminal I22, which is an inverting terminal of the differential amplifier 10, and keeps an output voltage Vout2 of the output terminal O20 constant.

At this time, in the differential amplifier 10, the differential amplification circuits 12A and 12B operate individually. Further, by making the voltage division ratio of the feedback resistors R0 and R1 different from the voltage division ratio of the feedback resistors R2 and R3, it is possible to generate individual output voltages Vout1 and Vout2.

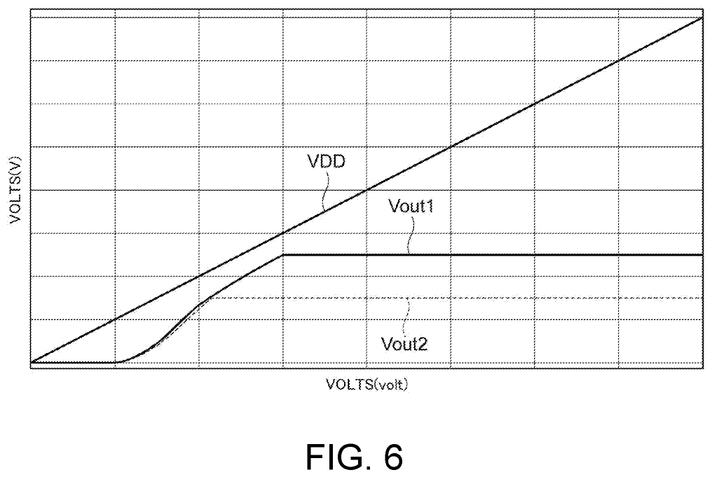

FIG. 6 shows a characteristics diagram of the output voltage of the regulator 50. It is learned that the regulator 50 generates individual output voltages Vout1 and Vout2 according to a power supply voltage VDD.

As described above, according to the regulator 50 of the fifth embodiment, since multiple inputs and multiple outputs can be provided with one regulator, it is possible to suppress an increase in the circuit scale compared to the conventional art in which multiple regulators are provided in the case where multiple outputs are required.

In the above embodiment, as an example, it has been described that the regulator 50 is formed using the differential amplifier 10 described in the first embodiment, but the disclosure is not limited thereto. As shown in FIG. 5, the regulator 50 may also be formed using the differential amplifier 20, 30, or 40 described in the second embodiment to the fourth embodiment.

### Sixth Embodiment

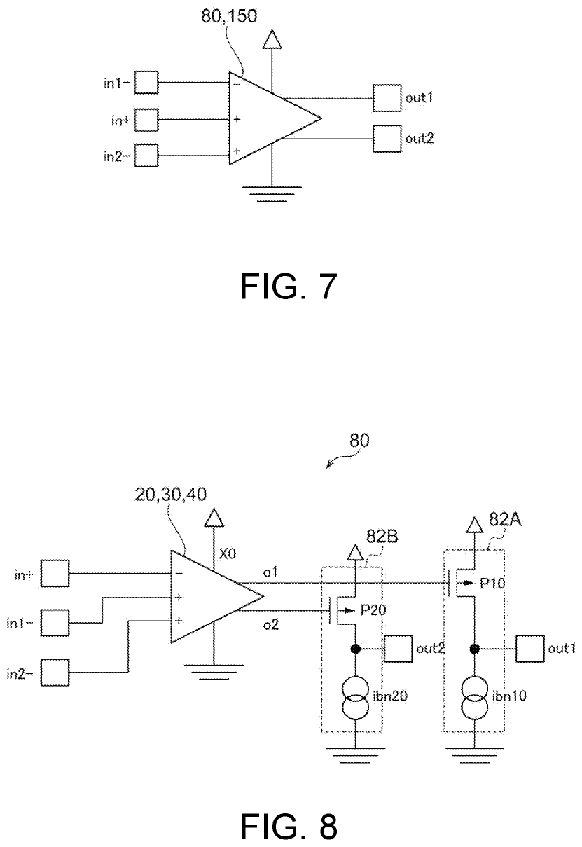

FIG. 7 is a circuit block diagram showing a configuration of an operational amplifier 80 according to a sixth embodiment of the disclosure.

The operational amplifier 80 is connected to input terminals in+, in1−, and in2−, and output terminals out1 and out2.

FIG. 8 is a circuit block diagram showing a specific configuration of the operational amplifier 80 according to the sixth embodiment shown in FIG. 7. As an example, the operational amplifier 80 will be described to include the differential amplifier 20 described in the second embodiment.

The first input terminal I1 of the differential amplifier 20 is connected to the input terminal in+, and the second input terminals I21 and I22 are connected to the input terminals in1− and in2−.

The output terminal O1 of the differential amplifier 20 is connected to the gate of a PMOS transistor P10. The operational amplifier 80 includes an amplification circuit 82A which is a series circuit including the PMOS transistor P10 and a bias current source ibn10. The source of the PMOS transistor P10 is connected to a power supply potential having a power supply voltage, and the drain of the PMOS transistor P10 is connected to the bias current source ibn10. One terminal of the bias current source ibn10 is connected to the drain of the PMOS transistor P10, and the other terminal of the bias current source ibn10 is connected to a ground potential having a ground voltage. The section between the drain of the PMOS transistor P10 and the one terminal of the bias current source ibn10 is connected to the output terminal out1.

The output terminal O2 of the differential amplifier 20 is connected to the gate of a PMOS transistor P20. The operational amplifier 80 includes an amplification circuit 82B which is a series circuit including the PMOS transistor P20 and a bias current source ibn20. The source of the PMOS transistor P20 is connected to the power supply potential, and the drain of the PMOS transistor P20 is connected to the bias current source ibn20. One terminal of the bias current source ibn20 is connected to the drain of the PMOS transistor P20, and the other terminal of the bias current source ibn20 is connected to the ground potential. The section between the drain of the PMOS transistor P20 and the one terminal of the bias current source ibn20 is connected to the output terminal out2.

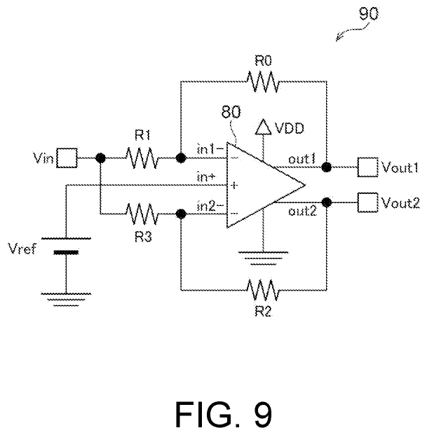

An inverting amplifier 90 as shown in FIG. 9, for example, is formed using the operational amplifier 80.

For example, a reference voltage Vref is applied to the input terminal in+ of the operational amplifier 80 in the inverting amplifier 90. Further, the input terminal in1− of the operational amplifier 80 is connected to an input voltage Vin and the output terminal out1 via feedback resistors R0 and R1. Further, the input terminal in2− of the operational amplifier 80 is connected to the input voltage Vin and the output terminal out2 via feedback resistors R2 and R3.

One terminal of the feedback resistor R0 is connected to the input terminal in1− of the operational amplifier 80, and the other terminal of the feedback resistor R0 is connected to the output terminal out1 of the operational amplifier 80. One terminal of the feedback resistor R1 is connected to the input voltage Vin, and the other terminal of the feedback resistor R1 is connected to the one terminal of the feedback resistor R0 and the input terminal in1− of the operational amplifier 80. One terminal of the feedback resistor R2 is connected to the input terminal in2− of the operational amplifier 80, and the other terminal of the feedback resistor R2 is connected to the output terminal out2 of the operational amplifier 80. One terminal of the feedback resistor R3 is connected to the input voltage Vin and the one terminal of the feedback resistor R1, and the other terminal of the feedback resistor R3 is connected to the one terminal of the feedback resistor R2 and the input terminal in2− of the operational amplifier 80.

The inverting amplifier 90 generates an output voltage Vout1 of “−N times” the input voltage Vin according to the resistance ratio of the feedback resistors R0 and R1, and generates an output voltage Vout2 of “−N times” the input voltage Vin according to the resistance ratio of the feedback resistors R2 and R3. At this time, in the differential amplifier 20, the differential amplification circuit 22 sharing a partial circuit connected to the first input terminal I1 operates individually. Further, by making the resistance ratio of the feedback resistors R0 and R1 different from the resistance ratio of the feedback resistors R2 and R3, the inverting amplifier 90 can generate output voltages of “−N times” individually as the output voltages Vout1 and Vout2.

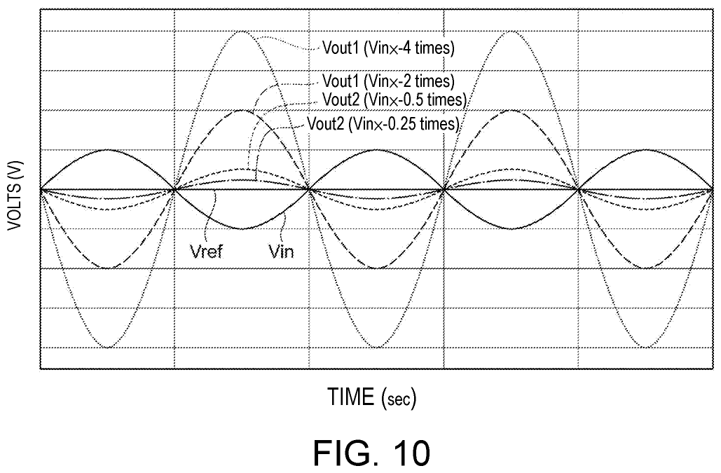

FIG. 10 shows a characteristics diagram of the output voltage of the inverting amplifier 90. It is learned that, by making the resistance ratio of the feedback resistors R0 and R1 different from the resistance ratio of the feedback resistors R2 and R3, output voltages Vout1 and Vout2 of “−N times” (e.g., N=0.25, 0.5, 2, 4) the input voltage Vin are generated individually.

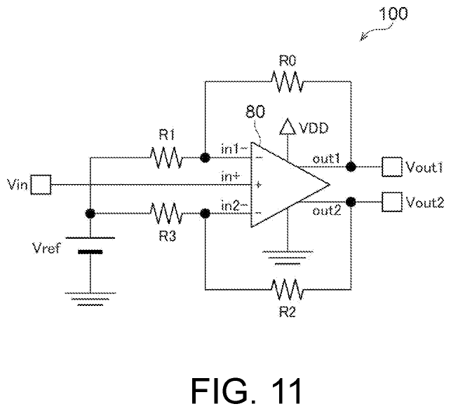

Further, a non-inverting amplifier 100 as shown in FIG. 11, for example, is formed using the operational amplifier 80.

For example, an input voltage Vin is applied to the input terminal in+ of the operational amplifier 80 in the non-inverting amplifier 100. Further, the input terminal in1− of the operational amplifier 80 is connected to a reference voltage Vref and the output terminal out1 via feedback resistors R0 and R1. Further, the input terminal in2− of the operational amplifier 80 is connected to the reference voltage Vref and the output terminal out2 via the feedback resistors R2 and R3.

The non-inverting amplifier 100 generates an output voltage Vout1 of “N times” the input voltage Vin according to the resistance ratio of the feedback resistors R0 and R1, and generates an output voltage Vout2 of “N times” the input voltage Vin according to the resistance ratio of the feedback resistors R2 and R3. At this time, in the differential amplifier 20, the differential amplification circuit 22 sharing a partial circuit connected to the first input terminal I1 operates individually. Further, by making the resistance ratio of the feedback resistors R0 and R1 different from the resistance ratio of the feedback resistors R2 and R3, the non-inverting amplifier 100 can generate output voltages of “N times” individually as the output voltages Vout1 and Vout2.

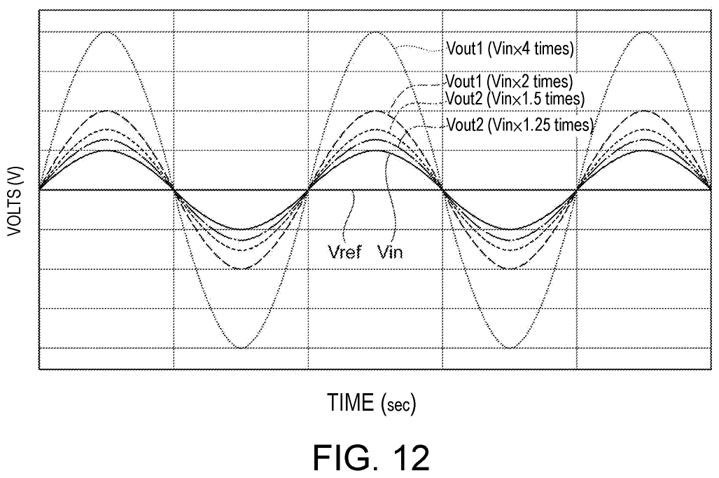

FIG. 12 shows a characteristics diagram of the output voltage of the non-inverting amplifier 100. It is learned that, by making the resistance ratio of the feedback resistors R0 and R1 different from the resistance ratio of the feedback resistors R2 and R3, output voltages Vout1 and Vout2 of “N times” (e.g., N=1.25, 1.5, 2, 4) the input voltage Vin are generated individually.

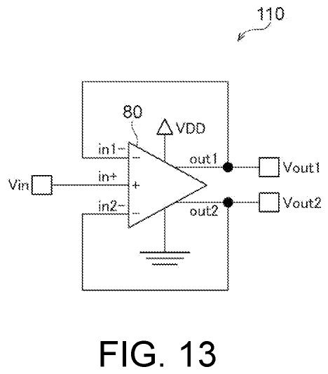

Further, a voltage follower 110 as shown in FIG. 13, for example, is formed using the operational amplifier 80.

For example, an input voltage Vin is applied to the input terminal in+ of the operational amplifier 80 in the voltage follower 110. Further, the input terminal in1− of the operational amplifier 80 is connected to the output terminal out1 of the operational amplifier 80 by a feedback node. Further, the input terminal in2− of the operational amplifier 80 is connected to the output terminal out2 of the operational amplifier 80 by a feedback node.

The voltage follower 110 generates output voltages of “1 time” the input voltage Vin.

At this time, in the differential amplifier 20, the differential amplification circuit 22 sharing a partial circuit connected to the first input terminal I1 operates individually. Further, the voltage follower 110 can generate output voltages of “1 time” individually as output voltages Vout1 and Vout2.

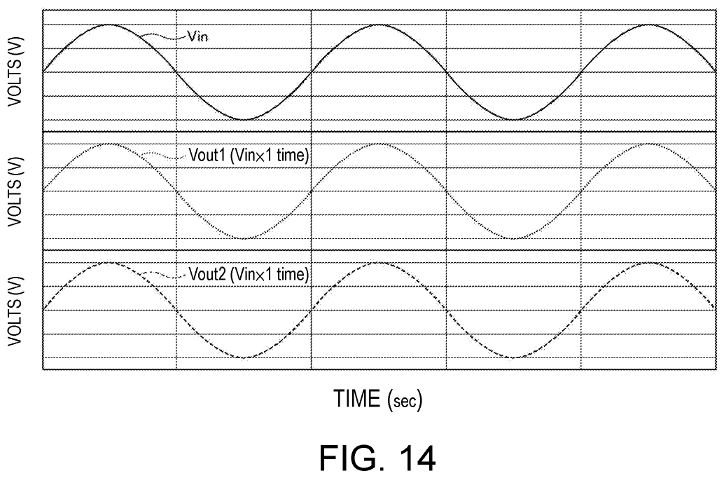

FIG. 14 shows a characteristics diagram of the output voltage of the voltage follower 110. It is learned that output voltages Vout1 and Vout2 of “1 time” the input voltage Vin are generated individually.

As described above, according to the operational amplifier 80 of the sixth embodiment, it is possible to form an inverting amplifier, a non-inverting amplifier, and a voltage follower of multiple inputs and multiple outputs with one operational amplifier. Thus, it is possible to suppress an increase in the circuit scale compared to the conventional art in which a plurality of these circuits are provided in the case where multiple outputs are required.

In the above embodiment, as an example, it has been described that the operational amplifier 80 is formed using the differential amplifier 20 described in the second embodiment, but the disclosure is not limited thereto. As shown in FIG. 8, the operational amplifier 80 may also be formed using the differential amplifier 30 or 40 described in the third embodiment or the fourth embodiment.

### Seventh Embodiment

FIG. 7 described above is a circuit block diagram showing a configuration of a comparator 150 according to a seventh embodiment of the disclosure.

The comparator 150 is connected to input terminals in+, in1−, and in2−, and output terminals out1 and out2.

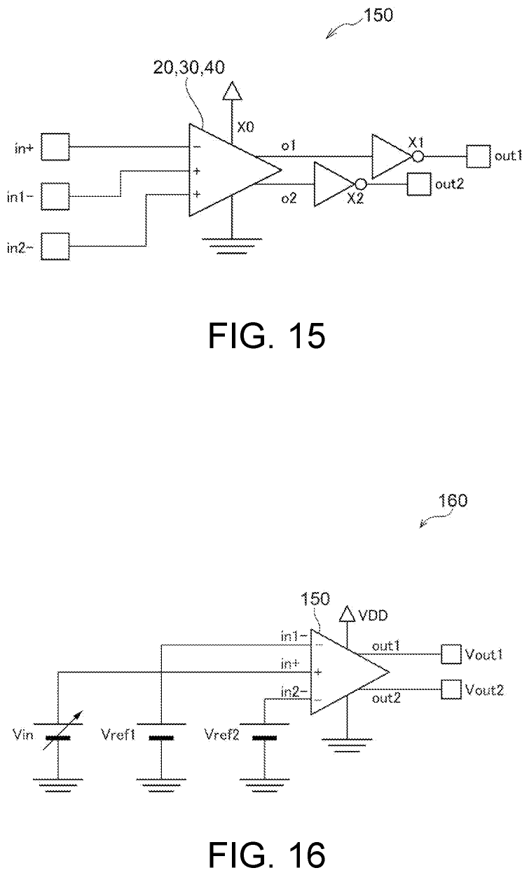

FIG. 15 is a circuit block diagram showing a specific configuration of the comparator 150 according to the seventh embodiment shown in FIG. 7. As an example, the comparator 150 will be described to include the differential amplifier 20 described in the second embodiment.

The first input terminal I1 of the differential amplifier 20 is connected to the input terminal in+, and the second input terminals I21 and I22 are connected to the input terminals in1− and in2−.

The output terminal O1 of the differential amplifier 20 is connected to the output terminal out1 via an inverter circuit X1.

The output terminal O2 of the differential amplifier 20 is connected to the output terminal out2 via an inverter circuit X2.

Further, a comparison device 160 as shown in FIG. 16, for example, is formed using the comparator 150.

For example, an input voltage Vin is applied to the input terminal in+ of the comparator 150 in the comparison device 160. Further, a reference voltage Vref1 is applied to the input terminal in1− of the comparator 150. Further, a reference voltage Vref2 is applied to the input terminal in2− of the comparator 150.

An output voltage Vout1 is outputted from the output terminal out1 of the comparator 150. Further, an output voltage Vout2 is outputted from the output terminal out2 of the comparator 150.

The comparison device 160 generates an output voltage according to a result of comparing the input voltage Vin and the reference voltage Vref1, and generates an output voltage according to a result of comparing the input voltage Vin and the reference voltage Vref2. At this time, in the differential amplifier 20, the differential amplification circuit 22 sharing a partial circuit connected to the first input terminal I1 operates individually. Further, by setting any reference voltages Vref1 and Vref2 with respect to the input voltage Vin, output voltages according to the comparison results are outputted individually as the output voltages Vout1 and Vout2.

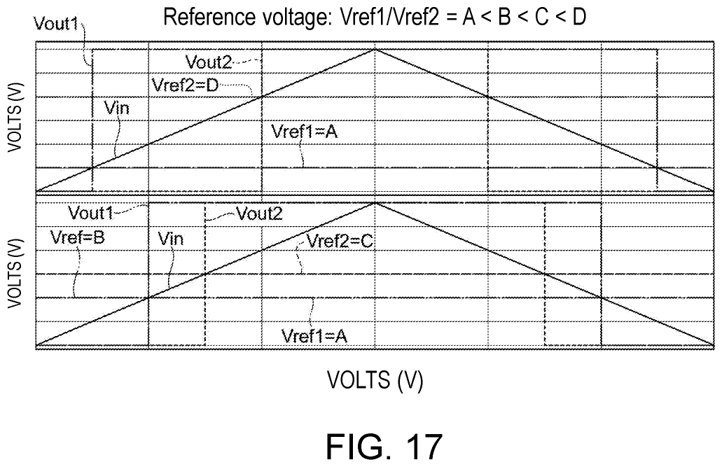

Upper and lower parts of FIG. 17 respectively show characteristics diagrams of the output voltage of the comparison device 160. It is learned that output voltages Vout1 and Vout2 are generated individually according to the comparison results in the case where Vref1/Vref2=A and A<B<C<D.

As described above, according to the comparator 150 of the seventh embodiment, it is possible to form a comparison device of multiple inputs and multiple outputs with one comparator. Thus, it is possible to suppress an increase in the circuit scale compared to the conventional art in which a plurality of these circuits are provided in the case where multiple outputs are required.

In the above embodiment, as an example, it has been described that the comparator 150 is formed using the differential amplifier 20 described in the second embodiment, but the disclosure is not limited thereto. As shown in FIG. 15, the comparator 150 may also be formed using the differential amplifier 30 or 40 described in the third embodiment or the fourth embodiment.

In each of above embodiments, as an example, it has been described that there are two second input terminals, but the disclosure is not limited thereto. There may also be three or more second input terminals. In that case, the output terminals and the differential amplification circuits may be provided in a same quantity as the second input terminals. In the differential amplifier having the same configuration as in the second embodiment and the fourth embodiment, the differential amplifier may be configured to be equivalent to the plurality of differential amplification circuits sharing a partial circuit connected to the first input terminal.

Further, in each of the above embodiments, as an example, it has been described that the load circuit is formed using a current mirror circuit, but the disclosure is not limited thereto. The load circuit may also be a cascode connection circuit or a circuit using diode connection.

Further, a phase compensation circuit may be further provided in each of the above embodiments.

Further, it is possible to use the above-described circuits in a bipolar process and a Bi-CMOS process. Further, it is also possible to use the above-described circuits as discrete components.

What is claimed is:

1. A differential amplifier comprising:
a first input terminal which is one of an inverting input terminal and a non-inverting input terminal;
a plurality of second input terminals, each of which is another of the inverting input terminal and the non-inverting input terminal;
a plurality of output terminals which output voltages respectively corresponding to the plurality of second input terminals;
a plurality of differential amplification circuits which are connected to the first input terminal and the plurality of second input terminals and are provided corresponding to the plurality of second input terminals; and
a current source circuit connected to the plurality of differential amplification circuits, wherein
each of the plurality of differential amplification circuits outputs an output voltage corresponding to a combination of a voltage inputted to the first input terminal and a voltage inputted to one of the plurality of second input terminals from a corresponding one of the plurality of output terminals.

2. The differential amplifier according to claim 1, wherein the plurality of differential amplification circuits share a partial circuit connected to the first input terminal.

3. The differential amplifier according to claim 1, wherein the plurality of differential amplification circuits comprise:
a plurality of load circuits connected to a first potential; and
a plurality of differential stage circuits connected to the first input terminal, the plurality of second input terminals, and the current source circuit.

4. The differential amplifier according to claim 2, wherein the plurality of differential amplification circuits comprise:
a load circuit connected to a first potential; and
a differential stage circuit connected to the first input terminal, the plurality of second input terminals, and the current source circuit, wherein
the partial circuit is a first transistor of the differential stage circuit connected to the first input terminal and a part of the load circuit connected to the first transistor.

5. The differential amplifier according to claim 3, wherein each of the plurality of differential stage circuits comprises a first transistor connected to the first input terminal and a second transistor connected to one of the plurality of second input terminals, and
the first transistor and the second transistor of each of the plurality of differential stage circuits are connected to the current source circuit.

6. The differential amplifier according to claim 3, wherein the current source circuit comprises a first current source transistor connected to the plurality of differential stage circuits.

7. The differential amplifier according to claim 3, further comprising a plurality of output stage circuits which are connected to the plurality of differential stage circuits and output voltages respectively to the plurality of output terminals.

8. A differential amplifier comprising:
a first differential stage circuit to which a reference voltage and a first input voltage are inputted;
a second differential stage circuit to which the reference voltage and a second input voltage are inputted;
a first load circuit provided between the first differential stage circuit and a first potential;
a second load circuit provided between the second differential stage circuit and the first potential; and
a current source circuit provided between a second potential, which is different from the first potential, and the first differential stage circuit and the second differential stage circuit.

9. The differential amplifier according to claim 8, wherein the current source circuit comprises a first current source transistor connected to the first differential stage circuit and the second differential stage circuit.

10. The differential amplifier according to claim 8, further comprising:
a first output stage circuit connected to a node at which the first differential stage circuit and the first load circuit are connected; and
a second output stage circuit connected to a node at which the second differential stage circuit and the second load circuit are connected.

11. A differential amplifier comprising:
a differential stage circuit comprising a first transistor to which a reference voltage is inputted, a second transistor to which a first input voltage is inputted, and a third transistor to which a second input voltage is inputted;
a load circuit provided between the differential stage circuit and a first potential; and
a current source circuit connected to the first transistor, the second transistor, and the third transistor, wherein
the differential stage circuit forms a first differential pair with the first transistor and the second transistor, and forms a second differential pair with the first transistor and the third transistor.

12. The differential amplifier according to claim 11, wherein the differential stage circuit outputs a first voltage from a first node at which the second transistor and the load circuit are connected, and outputs a second voltage from a second node at which the third transistor and the load circuit are connected.

13. The differential amplifier according to claim 11, wherein the current source circuit comprises a first current source transistor connected to the first transistor, the second transistor, and the third transistor.

14. The differential amplifier according to claim 13, wherein the current source circuit further comprises a bias current source and a second current source transistor connected to the bias current source, and
a gate of the first current source transistor and a gate of the second current source transistor are connected to a node at which the bias current source and the second current source transistor are connected.

15. The differential amplifier according to claim 11, wherein the load circuit comprises a first load transistor connected to the first transistor, a second load transistor connected to the second transistor, and a third load transistor connected to the third transistor, and
a gate of the first load transistor, a gate of the second load transistor, and a gate of the third load transistor are connected to each other.

16. The differential amplifier according to claim 11, further comprising: a first output stage circuit connected to a node at which the differential stage circuit and the load circuit are connected, the first input voltage being supplied to the first output stage circuit; and a second output stage circuit to which the second input voltage is supplied.
